(19) United States
(12) Patent Application Publication
(10) Pub. No.: US 2001/0030585 A1
(43) Pub. Date: Oct. 18, 2001

(54) Tunable filter and methods of characterizing and tuning said filter

(76) Inventors: Anders Jansson, Taby (SE); Lennart Larsson, Akersberga (SE); Bjorn Johansson, Taby (SE); Rolf Folkesson, Brottby (SE); Torbjorn Lindh, Huddinge (SE); Carl-Johan Wagner, Taby (SE)

Correspondence Address: JACOBSON HOLMAN PLLC, 400 SEVENTH STREET N.W., SUITE 600, WASHINGTON, DC, 20004, US

(21) Appl. No.: 09/784,327

(22) Filed: Feb. 16, 2001

(30) Foreign Application Priority Data
Feb. 16, 2000 (SE) 0000494-5

(51) Int. Cl. H03H 7/12

(52) U.S. Cl. 333/17.1; 333/132; 333/235

(57) ABSTRACT

A method for characterizing a frequency response of a tunable filter (11) includes the steps of adjusting a tuning means (12) to a first predetermined position; measuring the resonance frequency of the filter (10); temporary storing the measured resonance frequency and the position; and repeating these steps for a number of different predetermined positions of the tuning means. A mathematical function representing tuning means position as a function of resonance frequency is then determined, whereby several advantages are achieved. Little memory is required and the function provides for rapid and accurate tuning of the filter.

### FIELD OF INVENTION

The present invention relates generally to a method of characterizing a filter and more specifically a filter in a combiner. The invention also relates to a method of using this characterization when tuning the filter to a predetermined frequency, a method of building a mathematical model of a tunable filter, the tunable filter itself, and a combiner comprising such a tunable filter.

### BACKGROUND

A filter comprises one or more resonators, which can be of cavity, coaxial or dielectric type. The cavity itself can be the resonator without a dielectric one inside.

Filters are used in many high frequency electronic applications. One example thereof is in combiners used in a radio base station for mobile telecommunication and the function thereof is to combine several radio channels into a single antenna while maintaining inter channel isolation. This is accomplished with narrow band pass filters connected to an internal transmission line connected into a single antenna.

The resonant frequency of the filter is changed by varying the geometry thereof, e.g. by increasing or decreasing the effective volume of the cavity by means of an adjustment or tuning means actuated by e.g. an electric stepper motor. Thus, an effective volume of the cavity corresponds to a specific resonance frequency and each time the desired frequency is changed the motor moves the tuning means to a specific position.

It is desired that this change of frequency be effected as quickly and as accurately as possible so that no unnecessary delays are experienced when changing the frequency. To that end the filter can be characterized prior to use, thus enabling at least a rough tuning of the filter. A fine-tuning is then often performed, e.g. by measuring the reflected power of the filter.

A method for characterizing a frequency response of a resonant cavity filter is described in U.S. Pat. No. 5,739,731 (Hicks et al.). According to Hicks et al., a preferred method comprises the following steps: (a) inputting a first frequency signal to said resonant cavity filter; (b) changing dimensions of said resonant cavity until said resonant cavity resonates at said first frequency; (c) storing information relating to said dimensions of said resonant cavity which cause said resonant cavity to resonate at said first frequency; and (d) repeating steps (a), (b) and (c) for each frequency at which it is desired to know the frequency response of said resonant cavity filter thereby creating a look-up table.

The gist of the method according to Hicks et al. is the use of a look-up table. Thus, the inventive idea in Hicks et al. is to use the information stored in the look-up table to move the adjustment means, in this case a tuning plate, to a position close to the optimal position for the frequency in question.

However, there are several drawbacks connected with the prior art methods according to Hicks et al. Among these, the tuning plate is moved to an expected location. Thereafter, the tuning process is actually employed. Another drawback is that the filter can be tuned only to the measured RF frequencies. If the measured RE input frequency is between frequency data points recorded during the cavity characterization procedure, then a data interpolation is performed in order to find the expected tuning plate position to the nearest linear actuator step position. Another drawback is that during the characterization of the filter, step (b) takes some time because the internal control system of the combiner must move the tuning plate over a large part of its position range and determine that resonance has been achieved. Yet another drawback is that every single filter must be characterized, slowing down the manufacturing process. It is also difficult to take account to complex external phenomena, such as temperature, and change the look-up table. It is then needed a model or equation recalculating the table results.

### OBJECTS OF THE INVENTION

An object of the present invention is to provide a method of characterizing a tunable filter, which takes less time, is more accurate and requires less memory capacity than prior art methods.

Another object is to provide a method of building a mathematical model of a tunable filter.

Another object is to provide a combiner characterized by a method according to the invention.

Another object is to provide a tunable filter adapted for use with a method according to the invention and a combiner comprising such a filter.

Yet another object is to provide a method of using this characterization when tuning a filter to a desired frequency.

### SUMMARY OF THE INVENTION

The invention is based on the realization that a model mathematical function can be used for representation of the behavior of a filter.

According to the present invention there is provided a method for determining a resonant frequency characteristics of a tunable filter as defined in claim 1.

There is also provided a method of building a mathematical model of a tunable filter as defined in claim 12.

There is also provided a tunable filter as defined in claim 16 and a combiner comprising such a filter as defined in claim 21.

According to the present invention there is also provided a method for tuning a tunable filter as defined in claim 22.

With the filter and the methods according to the invention, several advantages are obtained. A filter is obtained which is quickly characterized and tuned. Also the memory requirement is less than with prior art filters.

With the methods according to the invention, it is possible to mass-produce filters without having to make a complete characterization of every filter, thereby providing more inexpensive and yet accurate end products.

### BRIEF DESCRIPTION OF DRAWINGS

The invention will now be described, by way of example, with reference to the accompanying drawings, in which:

FIG. 1 is a block diagram of a system for characterizing a resonant cavity filter;

FIG. 2 is a curve diagram characterizing a resonant cavity filter.

FIG. 3 is a block diagram of a system for tuning a resonant cavity filter; and

FIG. 4 is an alternative curve diagram characterizing a resonant cavity filter.

### DETAILED DESCRIPTION OF THE INVENTION

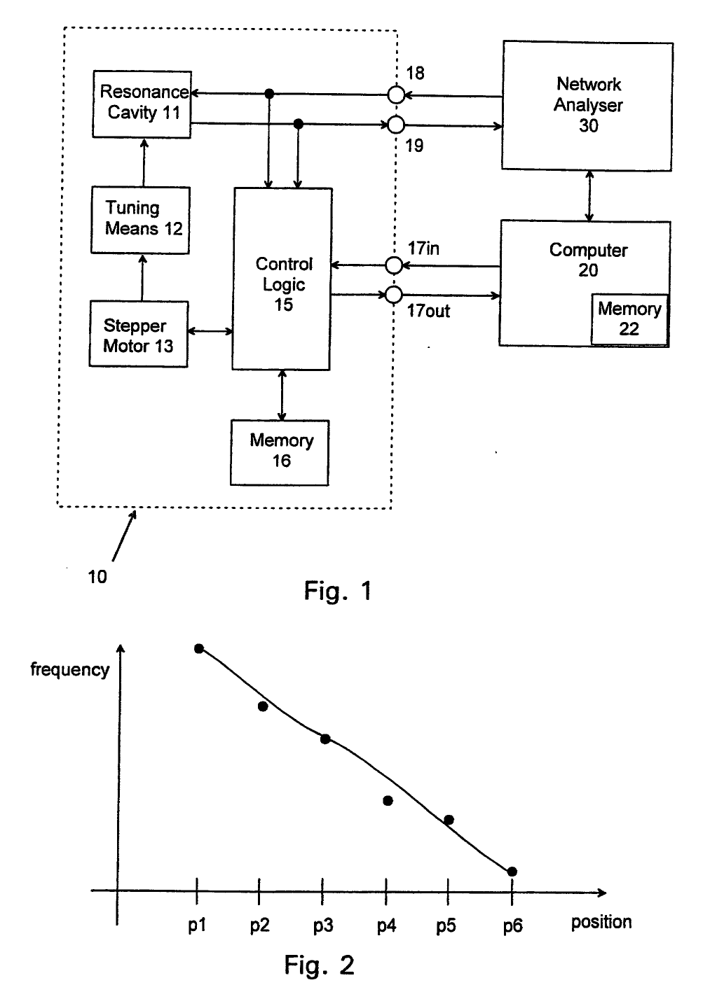

In the following, preferred embodiments of the invention will be described. In FIG. 1, a system for characterizing a resonant cavity filter is shown. The components comprising a combiner, generally designated 10, are surrounded by a broken line. The filter of the combiner comprises a resonant cavity 11, the size of which is adjusted by means of a tuning means 12, e.g. a tuning plate. The position of the tuning means is adjusted by means of a stepper motor 13. The resonant cavity 11 is connected to an input port 18 and an output port 19 for the input and output of external signals to/from the resonant cavity. The ports 18 and 19 are physically different connections. A control logic 15 controlling the operation of the combiner is also connected to the input and output ports 18 and 19. The logic 15 is also connected to the stepper motor 13 and a memory 16. This memory is provided for storing relevant data of the filter, which will be described below. Finally, the control logic 15 is connected directly to an input/output port 17in, 17out for connection to external devices.

When the filter is to be characterized, a computer 20 is connected to the port 17 communicating with the control logic 15 and a network analyzer 30 for analyzing the cavity filter is connected to the input/output ports 18, 19. The computer 20 and the analyzer 30 are also interconnected by means of e.g. a serial communication link.

A method for characterizing the filter 10 will now be described. First the tuning means 12 is moved to a known position by means of the stepper motor 13 under control of the control logic 15. The network analyzer 30 then analyses the filter in order to determine the current resonance frequency thereof. Information regarding the resonance frequency for the current tuning means position is transmitted to the computer 20 wherein this information is stored in a memory 22 for temporary information. In this memory is also stored information regarding the current position of the tuning means. Thus, this information comprises a frequency-position pair that characterizes the filter 10 for that particular frequency and position.

The tuning means is then moved to another position and the above procedure is repeated, thus giving another frequency-position pair stored in the memory 22 in the computer 20.

After a predetermined number of frequency-position pairs have been stored, the computer calculates a model mathematical function adapted to the stored information, i.e., the frequency as a function of position. With model mathematical function is meant an approximate function, i.e., it does not exactly describe the reality. Alternatively, a mathematical model is built, comprising models of the different components associated with the filter. This model can then be used for creating a model mathematical function.

An example of an approximate function is shown in FIG. 2, which is a curve diagram of frequency as a function of tuning means position. In the example of FIG. 2, six pairs for positions p1-p6 have been determined and a curve has been fitted to these points. This curve fitting can be accomplished in a number of ways, e.g. by means of a Least Square Method.

The mathematical function determined by the computer 20 is communicated to the control logic 15 of the combiner 10, wherein the inverse function thereof, i.e., the position as a function of frequency, it stored in the memory 16 in a convenient way known to the person skilled in the art.

This method entails several advantages over prior art. Among these there is the possibility of calculating unique output values for all input values. In the look-up table of prior art there is almost always an error in the interpolation between the measured points. The resolution is much better when the adaptation to the curve is good. Another advantage is that the function requires little memory space both in the memory 22 for temporary information and in the memory 16 of the filter 10 storing the calculated mathematical function. Another advantage is that the measuring process is much quicker and more accurate than in prior art methods because the resonance frequency can be measured by means of external equipment, i.e., the network analyzer 30.

Temperature compensation is provided by means of a separate mathematical function. This function can be the same for all filters of the same type or it can be unique for each filter, i.e., this function is determined during the above described characterization process. Other parameters, such as phase, Q-value, and S-parameters can also be incorporated in the mathematical function describing the filter.

By measuring many filters and analyzing the result, a function can be chosen wherein only a few factors are changed. The advantage is that only a few points must be measured in order to obtain an adequate function. This also saves time.

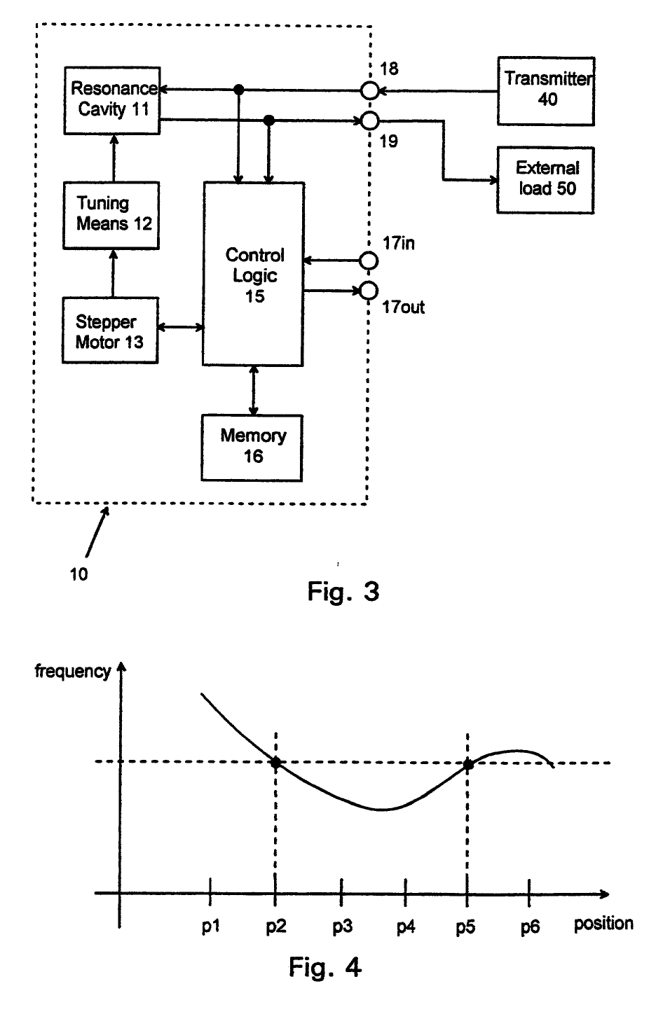

A method for tuning a resonant cavity filter will now be described with reference to FIG. 3, wherein a tuning set-up is shown. Instead of the network analyzer shown in FIG. 1, a transmitter 40 is connected to the input port 18 of the combiner 10, thus being connected to the resonant cavity 11 of the filter. Signals from the transmitter 40 are input to the port 18 and are directed to the resonant cavity 11. The frequency of the input signal is then determined by means of a frequency analyzer provided in the control logic 15. This determined frequency is used as a variable in the mathematical function stored in the memory 16 and the position of the tuning means 12 is calculated by the control logic 15. The control logic then sends a command to the stepper motor 13 in order to make it move the tuning means to the calculated position. The filtered signal is then output through the output port 19 to an external load 50, e.g. an antenna.

The above-described procedure provides for a quick and yet accurate method for tuning the filter to the frequency of the incoming signal. However, in some cases, a conventional fine-tuning is necessary in order to obtain an even more exact tuning of the filter.

In connection with the fine-tuning, an estimate of the deviation from the model mathematical function is obtained. A large deviation indicates a faulty component or at least a drift due to aging. In a preferred embodiment, a small deviation is compensated for by means of adjusting one or several of the function parameters. In connection with this, an alarm is given that the filter should be replaced, e.g. during the next service period. However, if the deviation is large, an alarm is given that the filter should be replaced immediately.

In the preferred embodiment, a one-pole filter is described. However, the method is also applicable to filters with more than one pole, e.g., filters with two poles and zeroes, depending on the filter requirements. It is obvious that for some filter types there are more than one position fulfilling the mathematical function, see FIG. 4. In that case, the function is modified, e.g. with logical decisions, so that for each frequency there is only one valid position. Alternatively, a sequential test is performed during tuning in order to determine the correct position.

In the preferred embodiment, the filter 11 is mounted in a combiner 10 in a radio base station of a radio communication system. The memory 16 can thus be situated anywhere in that combiner, e.g. in a central memory for several filters of a specific combiner.

In the described embodiment, a mathematical function is determined based on the measured values. This function can be adjusted by an adaptive process based on values measured during operation of the filter.

In the described example of the procedure for tuning the filter, the frequency of the input signal is determined by means of the control logic 15, e.g. by means of a frequency counter arrangement, spectrum analysis, DFT, FFT etc. However, it is also possible for that information to be included in a digital form via the computer interface 17. The control logic is then adapted for extracting that information from the input signal before the tuning process.

A band pass filter has been described. The man skilled in the art realizes that the invention is also applicable to other kinds of tunable filters, such as low pass, high pass and notch filters. These filters can be in the form of the above mentioned resonant cavity filters, but they can also be in the form of for example coaxial or dielectric resonators.

In an alternative embodiment, the inventive idea is implemented as a pre-stored mathematical model of a filter and other components associated therewith, such as stepper motors used for driving a tuning means, the screw pitch of screws connecting the motor and the means used for e.g. altering the physical dimensions of a filter cavity etc.

In this alternative embodiment, a model mathematical function is determined in accordance with the methods described above. Thus, for every relevant part of a system, such as a combiner, a mathematical model is provided. In that way, there is no need to check the properties of the individual components during manufacturing.

However, there are always some variations during assembly, partly due to mechanical or electrical tolerances. Therefore, as an optional step, the final system is measured for one or a few values, such as for some predetermined frequencies. In that way, the mathematical model can easily be adjusted to take account to the mechanical or electrical variations. In some systems, the variations can be compensated for by a constant added to the mathematical function. In those cases, one single adjustment measurement is sufficient to determine the compensation necessary. However, in those cases wherein the adjustment needed is more complex, two or more adjustment measurements are necessary.

An advantage with the model is that by making an additional measurement of the filter, it is easy to determine whether the filter is faulty. That is, if the tested point deviates too much from the model, there is something wrong with the filter.

When the final model mathematical function has been determined for a system, it is used during operation of the system. In case of a combiner with a filter adjusted by means of a stepper motor, the mathematical model is used, among other things, to determine the number of steps the motor shaft must be turned in order to move the adjustment means to a desired position. In that example it is clear how the mathematical description of the stepper motor and the pitch is involved in the use of the model in question.

1. A method for determining a resonant frequency characteristics of a tunable filter (11), said filter having a tuning means (12, 13),
characterized by the following steps:
(a) adjusting the tuning means (12) to a first predetermined position;
(b) establishing the resonance frequency characteristics of the filter (10) through measurements;
(c) temporarily storing the resulting resonance frequency characteristics and the positions;
(d) repeating steps (a)-(c) for second, and further predetermined positions of the tuning means;
(e) determining a model mathematical function representing tuning means position as a function of resonance frequency characteristics; and
(f) storing said mathematical function in a memory.

2. The method according to claim 1, wherein said model mathematical function represents resonant frequencies.

3. The method according to claim 1 or 2, wherein said model mathematical function is a polynomial.

4. The method according to claim 3, wherein the polynomial has an order of not higher than four.

5. The method according to claim 4, wherein the polynomial has an order of not higher than three.

6. The method according to any of the preceding claims, wherein the tunable filter (11) is one of the following types: cavity, coaxial and dielectric resonator.

7. The method according to any of the preceding claims, wherein the filter is part of a combiner.

8. The method according to any of the preceding claims, wherein the measuring of the resonance frequency of the filter performed in step (b) is effected by means of a network analyzer (30).

9. The method according to any of the preceding claims, wherein
step (b) comprises the additional step of measuring at least one of the following additional parameters of the filter: temperature, phase, Q-value, and S-parameters, and
the mathematical function determined in step (e) is also a function of said additional parameters.

10. The method according to any of the preceding claims, wherein the step (e) of determining a mathematical function involves a Least Square process.

11. The method according to any of the preceding claims, wherein the function is tested for multiple position values for one frequency and in the case multiple position values are found, only one position value is considered to be a valid position value.

12. A method of building a mathematical model of a tunable filter, characterized by the steps of:
(a) characterizing the filter according to claim 1;
(b) determining a mathematical model for at least some components associated with the filter; and
(c) compiling a model mathematical function for the filter and associated components.

13. The method according to claim 12, with the additional step (d) of compensating the model for mechanical or electrical variations by making compensation measurements.

14. The method according to claim 13, wherein the additional step (d) is performed during use of the filter.

15. The method according to claim 13 or 14, wherein the compensation measurements are used for determining a faulty filter by making a compensation measurement and, in case the compensation exceeds a predetermined value, determining that the filter is faulty.

16. A tunable filter, comprising:
a filter resonator (11);
a control means (15) connected to said filter resonator (11) and comprising means for determining a frequency of an input signal input to said filter resonator (11);
tuning means (12, 13) for tuning the filter, said tuning means being connected to said filter resonator (11) and said control means (15);
characterized by
an electronic memory (16) connected to said control means (15) and adapted for storing a position of the tuning means (12) as a mathematical function of the frequency of said input signal.

17. The filter according to claim 16, wherein said filter resonator (11) is a resonant cavity.

18. The filter according to claim 16 or 17, wherein the number of filter poles is one.

19. The filter according to claim 16 or 17, wherein the number of filter poles is at least two.

20. The filter according to any of claims 16-19, wherein the filter belongs to one of the following categories: band pass, low pass, and high pass filter.

21. A combiner for use in a radio communication system,
characterized by
a filter according to any of claims 16-20.

22. A method for tuning a tunable filter having a tuning means, characterized by the following steps:
(a) inputting a signal to said filter at an input thereof;
(b) determining a frequency or frequency characteristics of said signal;
(c) using a mathematical function representing a tuning means position as a function of said frequency or frequency characteristics for finding a tuning means position corresponding to said determined frequency or frequency characteristics; and
(d) moving said tuning means to said tuning means position.

23. The method according to claim 22, wherein there is an additional step (e) of fine-tuning the filter.

24. The method according to claim 22 or 23, wherein said mathematical function uses as a parameter at least one of the following parameters of the filter: temperature, phase, Q-value, and S-parameters.
